(19) United States
(12) Patent Application Publication
(10) Pub. No.: US 2025/0089441 A1
(43) Pub. Date: Mar. 13, 2025

(54) LIGHT EMITTING DIODE AND DISPLAY APPARATUS

(71) Applicant: BOE Technology Group Co., Ltd., Beijing (CN)

(72) Inventors: Lei Chen, Beijing (CN); Dan Wang, Beijing (CN); Xueqin Chen, Beijing (CN); Lixia Qiu, Beijing (CN)

(73) Assignee: BOE Technology Group Co., Ltd., Beijing (CN)

(21) Appl. No.: 18/576,025

(22) PCT Filed: Dec. 21, 2022
(86) PCT No.: PCT/CN2022/140541

§ 371 Date: Jan. 2, 2024

(51) Int. Cl. H10K 50/12; H10K 50/15; H10K 50/18; H10K 50/86; H10K 85/60; H10K 101/40; H10K 102/00

(52) U.S. Cl. CPC H10K 50/12; H10K 50/15; H10K 50/181; H10K 50/865; H10K 85/657; H10K 2101/40; H10K 2102/351

(57) ABSTRACT

A light emitting diode is provided. The light emitting diode includes a hole injection layer; and at least one of a hole transport layer or an electron barrier layer. The hole injection layer includes a host material doped with a guest material. The host material includes an aromatic material having one or more large steric hindrance groups.

### TECHNICAL FIELD

The present invention relates to display technology, more particularly, to a light emitting diode and a display apparatus.

### BACKGROUND

Organic Light Emitting Diode (OLED) display is one of the hotspots in the field of flat panel display research today. Unlike Thin Film Transistor-Liquid Crystal Display (TFT-LCD), which uses a stable voltage to control brightness, OLED is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides a light emitting diode, comprising a hole injection layer; and at least one of a hole transport layer or an electron barrier layer; wherein the hole injection layer comprises a host material doped with a guest material; wherein the host material comprises an aromatic material having one or more large steric hindrance groups.

Optionally, wherein the aromatic material having one or more large steric hindrance groups has a formula of:

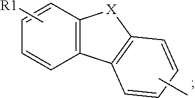

wherein X is —O—, —S—,

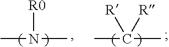

and R0, R′, R″, and R1 are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted aryl alkyl, substituted or unsubstituted alkyl silyl, or substituted or unsubstituted aryl silyl.

Optionally, the aromatic material having one or more large steric hindrance groups has a formula of:

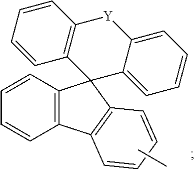

wherein —Y— is bond (e.g., a single bond), —O—, —S—,

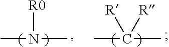

and R0, R′, and R″ are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted aryl alkyl, substituted or unsubstituted alkyl silyl, or substituted or unsubstituted aryl silyl.

Optionally, the guest material of the hole injection layer comprises a cyanide group and fluorine element.

Optionally, the guest material has a formula of:

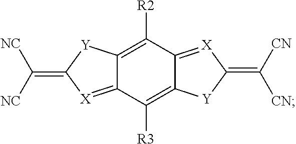

X is N, or C—R4; Y is O, S, or

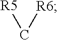

R2 and R3 contain one or more fluorine atoms, and are independently substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted aryl alkyl, substituted or unsubstituted alkoxy, or substituted or unsubstituted aryloxy; and R4, R5, and R6 are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted aryl alkyl, substituted or unsubstituted alkoxy, or substituted or unsubstituted aryloxy.

Optionally, a difference between a lowest unoccupied molecular orbital energy level of the guest material of the hole injection layer and a highest occupied molecular orbital energy level of a host material of the hole injection layer is less than 0.3 eV.

Optionally, when the hole injection layer has a thickness of 10 nm and a doping concentration of the guest material in the hole injection layer is 3%, a sheet resistance of the host material of the hole injection layer is equal to or greater than 1*10⁹ Ω/sq.

Optionally, when the hole injection layer has a thickness of 10 nm and a doping concentration of the guest material in the hole injection layer is 2%, a sheet resistance of the host material of the hole injection layer is equal to or greater than 1*10¹⁰ Ω/sq.

Optionally, the light emitting diode further comprises the hole transport layer including a host transport material; wherein the host transport material comprises an aromatic material having one or more large steric hindrance groups.

Optionally, the aromatic material having one or more large steric hindrance groups has a formula of:

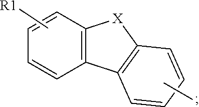

wherein X is —O—, —S—,

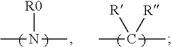

and R0, R′, R″, and R1 are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted aryl alkyl, substituted or unsubstituted alkyl silyl, or substituted or unsubstituted aryl silyl.

Optionally, the aromatic material having one or more large steric hindrance groups has a formula of:

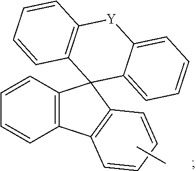

wherein —Y— is bond (e.g., a single bond), —O—, —S—,

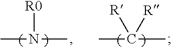

and R0, R′, and R″ are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted aryl alkyl, substituted or unsubstituted alkyl silyl, or substituted or unsubstituted aryl silyl.

Optionally, the light emitting diode further comprises the electron barrier layer; wherein the electron barrier layer comprises an electron barrier material including an aromatic material having a dibenzo group and an adamantyl group; and

wherein the adamantyl group has a formula of

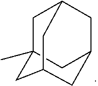

Optionally, the dibenzo group has a formula of.

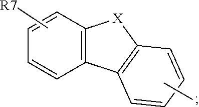

wherein X is —O—, —S—,

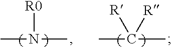

and R7 is substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted aryl alkyl, substituted or unsubstituted alkyl silyl, or substituted or unsubstituted aryl silyl.

Optionally, a difference between a highest occupied molecular orbital energy level of the hole transport layer and a highest occupied molecular orbital energy level of the electron barrier layer is less than 0.2 eV.

Optionally, a mobility rate of the electron barrier layer is in a range of 1*10⁻⁵ cm²/Vs to 1*10⁻⁴ cm²/Vs.

Optionally, hole carrier transmits through the electron barrier layer in a duration less than 3 μs.

Optionally, the light emitting diode further comprises a cathode layer and a capping layer on a side of the cathode layer away from the hole injection layer; wherein the capping material comprises a conjugate diene having a formula of:

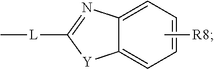

wherein Y is O, S, or

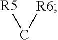

L is bond, substituted or unsubstituted alkylene, substituted or unsubstituted heteroalkylene, substituted or unsubstituted cycloalkylene, substituted or unsubstituted heterocycloalkylene, substituted or unsubstituted arylene, substituted or unsubstituted heteroarylene, —N(R′″)—, —C(O)—, or —O—; R8 is hydrogen, deuterium, halide, substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted alkyl silyl, or substituted or unsubstituted aryl silyl; and R′″, R5, and R6 are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl.

Optionally, the light emitting diode further comprises a cathode layer and a capping layer on a side of the cathode layer away from the hole injection layer; wherein the capping material comprises a conjugate diene having a formula of:

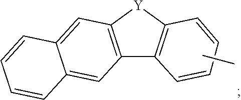

wherein Y is O, S, or

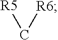

and R5 and R6 are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl.

Optionally, the light emitting diode further comprises a cathode layer and a capping layer on a side of the cathode layer away from the hole injection layer; wherein the capping layer has an absorption rate greater than 20% with respect to ultraviolet light having a wavelength of 400 nm, and an absorption rate greater than 15% with respect to ultraviolet light having a wavelength of 420 nm; and the capping layer has an absorption rate less than 3% with respect to light having a wavelength in a range of 460 nm to 530 nm, and an absorption rate less than 2% with respect to light having a wavelength in a range of 530 nm to 620 nm.

In another aspect, the present disclosure provides a display apparatus, comprising the light emitting diode described herein, and a pixel driving circuit configured to drive light emission of the light emitting diode.

### BRIEF DESCRIPTION OF THE FIGURES

The following drawings are merely examples for illustrative purposes according to various disclosed embodiments and are not intended to limit the scope of the present invention.

FIG. 1 illustrates a detailed structure in a display area in a display apparatus in some embodiments according to the present disclosure.

FIG. 2 illustrates the structure of a pixel in a display panel in some embodiments according to the present disclosure.

FIG. 3 illustrates the structure of a light emitting diode in some embodiments according to the present disclosure.

FIG. 4 shows a light emission spectrum in a related light emitting diode.

FIG. 5 shows a light emission spectrum in a light emitting diode in some embodiments according to the present disclosure.

FIG. 6 is a circuit diagram illustrating the structure of a pixel driving circuit in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

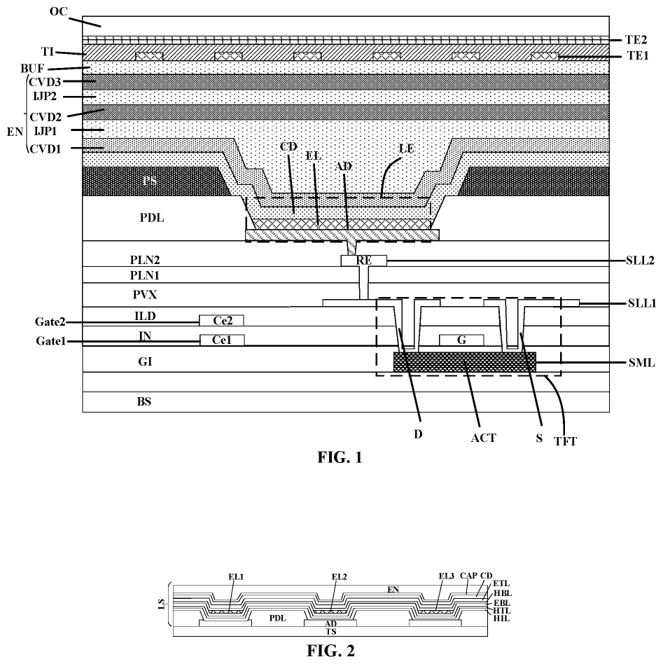

FIG. 1 illustrates a detailed structure in a display area in a display apparatus in some embodiments according to the present disclosure. Referring to FIG. 1, the display apparatus in the display area in some embodiments includes a base substrate BS (e.g., a flexible base substrate); an active layer ACT of a respective one of a plurality of thin film transistors TFT on the base substrate BS; a gate insulating layer GI on a side of the active layer ACT away from the base substrate BS; a gate electrode G and a first capacitor electrode Ce1 (both are parts of a first gate metal layer) on a side of the gate insulating layer GI away from the base substrate BS; an insulating layer IN on a side of the gate electrode G and the first capacitor electrode Ce1 away from the gate insulating layer GI; a second capacitor electrode Ce2 (a part of a second gate metal layer) on a side of the insulating layer IN away from the gate insulating layer GI; an inter-layer dielectric layer ILD on a side of the second capacitor electrode Ce2 away from the gate insulating layer GI; a source electrode S and a drain electrode D (parts of a first SD metal layer) on a side of the inter-layer dielectric layer ILD away from the gate insulating layer GI; a passivation layer PVX on a side of the source electrode S and the drain electrode D away from the inter-layer dielectric layer ILD; a first planarization layer PLN1 on a side of the passivation layer PVX away from the inter-layer dielectric layer ILD; a relay electrode RE (part of a second SD metal layer) on side of the first planarization layer PLN1 away from the passivation layer PVX; a second planarization layer PLN2 on a side of the relay electrode RE (part of a second SD metal layer) away from the first planarization layer PLN1; a pixel definition layer PDL defining a subpixel aperture and on a side of the second planarization layer PLN2 away from the base substrate BS; and a light emitting element LE in the subpixel aperture. The light emitting element LE includes an anode AD on a side of the second planarization layer PLN2 away from the first planarization layer PLN1; a light emitting layer EL on a side of the anode AD away from the second planarization layer PLN2; and a cathode layer CD on a side of the light emitting layer EL away from the anode AD. The display apparatus in the display area further includes an encapsulating layer EN encapsulating the light emitting element LE, and on a side of the cathode layer CD away from the base substrate BS.

The encapsulating layer EN in some embodiments includes a first inorganic encapsulating sub-layer CVD1 on a side of the cathode layer CD away from the base substrate BS, a first organic encapsulating sub-layer IJP1 on a side of the first inorganic encapsulating sub-layer CVD1 away from the base substrate BS, a second inorganic encapsulating sub-layer CVD2 on a side of the first organic encapsulating sub-layer IJP1 away from the base substrate BS, a second organic encapsulating sub-layer IJP2 on a side of the second inorganic encapsulating sub-layer CVD2 away from the base substrate BS, and a third inorganic encapsulating sub-layer CVD3 on a side of the second organic encapsulating sub-layer IJP2 away from the base substrate BS. In alternative embodiments, the encapsulating layer EN does not include the second organic encapsulating sub-layer IJP2 and the third inorganic encapsulating sub-layer CVD3.

The display apparatus in the display area further includes a buffer layer BUF on a side of the encapsulating layer EN away from the base substrate BS; a first touch electrode layer TE1 on a side of the buffer layer BUF away from the encapsulating layer EN; a touch insulating layer TI on a side of the first touch electrode layer TE1 away from the buffer layer BUF; a second touch electrode layer TE2 on a side of the touch insulating layer TI away from the buffer layer BUF; and an overcoat layer OC on a side of the second touch electrode layer TE2 away from the touch insulating layer TI.

Referring to FIG. 1, the display apparatus includes a semiconductor material layer SML, a first gate metal layer Gate1, a second gate metal layer Gate2, a first signal line layer SLL1, and a second signal line layer SLL2. The display apparatus further includes an insulating layer IN between the first gate metal layer Gate1 and the second gate metal layer Gate2; an inter-layer dielectric layer ILD between the second conductive layer Gate2 and the first signal line layer SLL1; and at least a passivation layer PVX or a planarization layer PLN between the first signal line layer SLL1 and the second signal line layer SLL2.

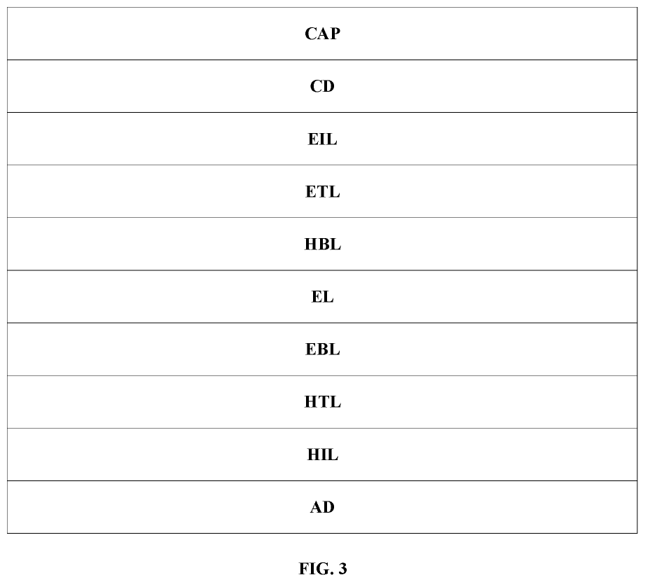

FIG. 2 illustrates the structure of a pixel in a display panel in some embodiments according to the present disclosure. Referring to FIG. 2, the display panel in some embodiments includes a transistor substrate TS having a plurality of pixel driving circuits for driving light emission of a plurality of light emitting elements; and a light emitting substrate LS comprising a plurality of light emitting elements. Various appropriate light emitting elements may be used in the present array substrate. Examples of appropriate light emitting elements include organic light emitting diodes, quantum dots light emitting diodes, and micro light emitting diodes. Optionally, the light emitting element is micro light emitting diode.

FIG. 2 shows a pixel of the related display panel. The pixel includes at least three subpixels (e.g., a red subpixel, a green subpixel, and a blue subpixel). The light emitting substrate LS includes an anode AD and a pixel definition layer PDL defining a plurality of subpixel apertures on the transistor substrate TS, a hole injection layer HIL on a side of the anode AD away from the transistor substrate TS, a hole transport layer HTL on a side of the hole injection layer HIL away from the transistor substrate TS, an electron barrier layer EBL on a side of the hole transport layer HTL away from the transistor substrate TS, a plurality of light emitting layers (including a first light emitting layer EL1, a second light emitting layer EL2, and a third light emitting layer EL3) on a side of the electron barrier layer EBL away from the transistor substrate TS and in the plurality of subpixel apertures, a hole barrier layer HBL on a side of the plurality of light emitting layers away from the transistor substrate TS, an electron transport layer ETL on a side of the hole barrier layer HBL away from the transistor substrate TS, a cathode CD on a side of the electron transport layer ETL away from the transistor substrate TS, a capping layer CAP on a side of the cathode CD away from the transistor substrate TS, and an encapsulating layer EN on a side of the capping layer CAP away from the transistor substrate TS.

As shown in FIG. 2, a hole transport layer HTL, a hole injection layer HIL, a hole barrier layer HBL, and an electron transport layer ETL are common layers extending throughout a plurality of subpixels in the related display panel. The inventors of the present disclosure discover that a p-doped hole injection layer can optimize carrier injection. By doping the hole injection layer with a p-type dopant, an amount of hole carriers injected from the anode AD can be increased, the increase in mobility rate improves the voltage of the device. The inventors of the present disclosure discover that a horizontal current leakage in a p-doped hole injection layer is observed because the hole injection layer is a common layer, as discussed above. For example, when a green subpixel is configured to emit light while the red subpixel is turned off, residual light emission is nonetheless observed in the red subpixel due to the horizontal current leakage in the common layers such as the hole injection layer HIL, resulting in color cross-talk.

Accordingly, the present disclosure provides, inter alia, a light emitting diode and a display apparatus that substantially obviate one or more of the problems due to limitations and disadvantages of the related art. In one aspect, the present disclosure provides a light emitting diode. In some embodiments, the light emitting diode includes a hole injection layer. In some embodiments, the hole injection layer includes a host material doped with a guest material. Optionally, the host material includes an aromatic material having one or more large steric hindrance groups.

In some embodiments, the hole injection layer includes a host material and a guest material. In some embodiments, the host material includes an aromatic material having one or more large steric hindrance groups. The inventors of the present disclosure discover that, by using the aromatic materials having one or more large steric hindrance groups, the horizontal current leakage in the hole injection layer can be effectively suppressed. The inventors of the present disclosure discover that the hole injection layer having the aromatic material having the one or more large steric hindrance groups has an anisotropic electrical property, e.g., the hole injection layer has a large horizontal resistance than its vertical resistance, thereby significantly decreasing the horizontal current leakage in the hole injection layer.

In some embodiments, the aromatic material having one or more large steric hindrance groups has a formula of.

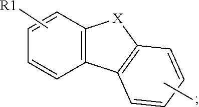

wherein X is —O—, —S—,

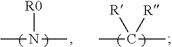

R0, R′, R″, and R1 are independently hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), substituted or unsubstituted heteroaryl (e.g. 5 to 14 membered heteroaryl including fused rings structures), substituted or unsubstituted aryl alkyl, substituted or unsubstituted alkyl silyl, or substituted or unsubstituted aryl silyl.

Optionally, R0, R′, R″, and R1 are independently substituted or unsubstituted aryl having 6 to 40 carbon atoms, substituted or unsubstituted cycloalkyl having 6 to 40 carbon atoms, substituted or unsubstituted heterocycloalkyl having 3-40 carbon atoms, substituted or unsubstituted alkyl having 1 to 20 carbon atoms, substituted or unsubstituted heteroalkyl having 1 to 20 carbon atoms, substituted or unsubstituted aryl alkyl having 7-30 carbon atoms, substituted or unsubstituted heteroaryl having 3-40 carbon atoms, substituted or unsubstituted alkyl silyl having 3-20 carbon atoms, or substituted or unsubstituted aryl silyl having 6-20 carbon atoms.

In some embodiments, the aromatic material having one or more large steric hindrance groups has a formula of:

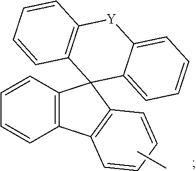

wherein —Y— is bond (e.g., a single bond), —O—, —S—,

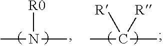

R0, R′, and R″ are independently hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), substituted or unsubstituted heteroaryl (e.g. 5 to 14 membered heteroaryl including fused rings structures), substituted or unsubstituted aryl alkyl, substituted or unsubstituted alkyl silyl, or substituted or unsubstituted aryl silyl.

Optionally, R0, R′, and R″ are independently substituted or unsubstituted aryl having 6 to 40 carbon atoms, substituted or unsubstituted cycloalkyl having 6 to 40 carbon atoms, substituted or unsubstituted heterocycloalkyl having 3-40 carbon atoms, substituted or unsubstituted alkyl having 1 to 20 carbon atoms, substituted or unsubstituted heteroalkyl having 1 to 20 carbon atoms, substituted or unsubstituted aryl alkyl having 7-30 carbon atoms, substituted or unsubstituted heteroaryl having 3-40 carbon atoms, substituted or unsubstituted alkyl silyl having 3-20 carbon atoms, or substituted or unsubstituted aryl silyl having 6-20 carbon atoms.

In some embodiments, the hole injection layer includes a host material and a guest material (e.g., a p-type guest material). In some embodiments, the guest material of the hole injection layer includes a cyanide group and fluorine element. The inventors of the present disclosure discover that, by using the guest material having the cyanide group and fluorine element, the guest material has an enhanced electron absorption ability, and the lowest unoccupied molecular orbital energy level can be further lowered. The p-type dopant effects using the guest material having the cyanide group and fluorine element becomes more prominent, increasing hole carrier density.

In some embodiments, the guest material having the cyanide group and fluorine element has a formula of:

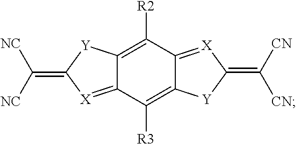

wherein X is N, or C—R4; Y is O, S, or

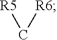

R2 and R3 contain one or more fluorine atoms and are independently substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), substituted or unsubstituted heteroaryl (e.g. 5 to 14 membered heteroaryl including fused rings structures), substituted or unsubstituted aryl alkyl, substituted or unsubstituted alkoxy, or substituted or unsubstituted aryloxy; R4, R5, and R6 are independently hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), substituted or unsubstituted heteroaryl (e.g. 5 to 14 membered heteroaryl including fused rings structures), substituted or unsubstituted aryl alkyl, substituted or unsubstituted alkoxy, or substituted or unsubstituted aryloxy.

Optionally, R2 and R3 contain one or more fluorine atoms and are independently substituted or unsubstituted alkyl having 1-20 carbon atoms, substituted or unsubstituted cycloalkyl having 3-20 carbon atoms, substituted or unsubstituted heteroalkyl having 1-20 carbon atoms, substituted or unsubstituted aryl alkyl having 7-30 carbon atoms, substituted or unsubstituted alkoxy having 1-20 carbon atoms, or substituted or unsubstituted aryloxy having 6-30 carbon atoms. Optionally, R4, R5, and R6 are independently substituted or unsubstituted cycloalkyl having 3-20 carbon atoms, substituted or unsubstituted heteroalkyl having 1-20 carbon atoms, substituted or unsubstituted aryl alkyl having 7-30 carbon atoms, substituted or unsubstituted alkoxy having 1-20 carbon atoms, or substituted or unsubstituted aryloxy having 6-30 carbon atoms.

In some embodiments, the hole transport layer includes an aromatic material having one or more large steric hindrance groups. The inventors of the present disclosure discover that, by using the aromatic materials having one or more large steric hindrance groups, the horizontal current leakage in the hole transport layer can be effectively suppressed. The inventors of the present disclosure discover that the hole transport layer having the aromatic material having the one or more large steric hindrance groups has an anisotropic electrical property, e.g., the hole transport layer has a large horizontal resistance than its vertical resistance, thereby significantly decreasing the horizontal current leakage in the hole transport layer.

In some embodiments, the hole transport layer includes a same material as the host material of the hole injection layer.

In some embodiments, the aromatic material having one or more large steric hindrance groups has a formula of:

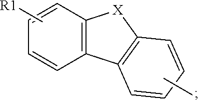

wherein X is —O—, —S—,

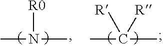

R0, R′, R″, and R1 are independently hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), substituted or unsubstituted heteroaryl (e.g. 5 to 14 membered heteroaryl including fused rings structures), substituted or unsubstituted aryl alkyl, substituted or unsubstituted alkyl silyl, or substituted or unsubstituted aryl silyl.

Optionally, R0, R′, R″, and R1 are independently substituted or unsubstituted aryl having 6 to 40 carbon atoms, substituted or unsubstituted cycloalkyl having 6 to 40 carbon atoms, substituted or unsubstituted heterocycloalkyl having 3-40 carbon atoms, substituted or unsubstituted alkyl having 1 to 20 carbon atoms, substituted or unsubstituted heteroalkyl having 1 to 20 carbon atoms, substituted or unsubstituted aryl alkyl having 7-30 carbon atoms, substituted or unsubstituted heteroaryl having 3-40 carbon atoms, substituted or unsubstituted alkyl silyl having 3-20 carbon atoms, or substituted or unsubstituted aryl silyl having 6-20 carbon atoms.

In some embodiments, the aromatic material having one or more large steric hindrance groups has a formula of:

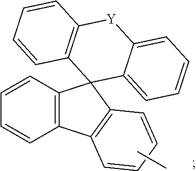

wherein —Y— is bond (e.g., a single bond), —O—, —S—,

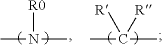

R0, R′, and R″ are independently hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), substituted or unsubstituted heteroaryl (e.g. 5 to 14 membered heteroaryl including fused rings structures), substituted or unsubstituted aryl alkyl, substituted or unsubstituted alkyl silyl, or substituted or unsubstituted aryl silyl.

Optionally, R0, R′, and R″ are independently substituted or unsubstituted aryl having 6 to 40 carbon atoms, substituted or unsubstituted cycloalkyl having 6 to 40 carbon atoms, substituted or unsubstituted heterocycloalkyl having 3-40 carbon atoms, substituted or unsubstituted alkyl having 1 to 20 carbon atoms, substituted or unsubstituted heteroalkyl having 1 to 20 carbon atoms, substituted or unsubstituted aryl alkyl having 7-30 carbon atoms, substituted or unsubstituted heteroaryl having 3-40 carbon atoms, substituted or unsubstituted alkyl silyl having 3-20 carbon atoms, or substituted or unsubstituted aryl silyl having 6-20 carbon atoms.

In some embodiments, the electron barrier layer includes an electron barrier material including an aromatic material having a dibenzo group and an adamantyl group. The inventors of the present disclosure discover that, by having the dibenzo group, the mobility of the electron barrier layer can be enhanced to compensate a reduced carrier density due to the one or more large steric hindrance groups introduced into the hole transport material in the hole transport layer. By having the adamantyl group, the thermal stability of the electron barrier layer can be increased.

The adamantyl group has a formula of

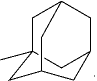

In some embodiments, the dibenzo group has a formula of:

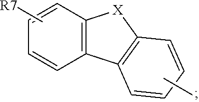

wherein X is —O—, —S—,

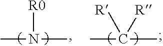

R7 is substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), substituted or unsubstituted heteroaryl (e.g. 5 to 14 membered heteroaryl including fused rings structures), substituted or unsubstituted aryl alkyl, substituted or unsubstituted alkyl silyl, or substituted or unsubstituted aryl silyl. Optionally, R7 contains the adamantyl group, e.g., the adamantyl group is at least a portion of R7.

Optionally, R7 substituted or unsubstituted aryl having 6 to 40 carbon atoms, substituted or unsubstituted cycloalkyl having 6 to 40 carbon atoms, substituted or unsubstituted heterocycloalkyl having 3-40 carbon atoms, substituted or unsubstituted alkyl having 1 to 20 carbon atoms, substituted or unsubstituted heteroalkyl having 1 to 20 carbon atoms, substituted or unsubstituted aryl alkyl having 7-30 carbon atoms, substituted or unsubstituted heteroaryl having 3-40 carbon atoms, substituted or unsubstituted alkyl silyl having 3-20 carbon atoms, or substituted or unsubstituted aryl silyl having 6-20 carbon atoms. Optionally, R7 contains the adamantyl group, e.g., the adamantyl group is at least a portion of R7.

In some embodiments, the capping layer includes a capping material comprising conjugated dienes. In some embodiments, the capping material includes two or more conjugated rings. In some embodiments, the capping material includes two or more planes each having a conjugated ring, wherein dihedral angles between two or more planes are substantially 180 degrees, e.g., 170 degrees to 190 degrees. The inventors of the present disclosure discover that, by using the capping material according to the present disclosure, a refractive index of the capping layer can be enhanced to increase light extraction efficiency of a light emitting diode having the capping layer.

In some embodiments, the capping material includes a conjugate diene having a formula of:

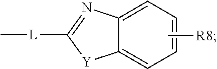

wherein Y is O, S, or

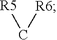

L is bond, substituted or unsubstituted alkylene, substituted or unsubstituted heteroalkylene, substituted or unsubstituted cycloalkylene, substituted or unsubstituted heterocycloalkylene, substituted or unsubstituted arylene, substituted or unsubstituted heteroarylene, —N(R′″)—, —C(O)—, or —O—; R8 is hydrogen, deuterium, halide (e.g., chloride, fluoride, bromide, iodide), substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), substituted or unsubstituted heteroaryl (e.g. 5 to 14 membered heteroaryl including fused rings structures), substituted or unsubstituted alkyl silyl, or substituted or unsubstituted aryl silyl; R′″, R5, and R6 are independently hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), or substituted or unsubstituted heteroaryl (e.g. 5 to 14 membered heteroaryl including fused rings structures).

Optionally, R8 is hydrogen, deuterium, halide, substituted or unsubstituted alkyl with 1-20 carbon atoms, substituted or unsubstituted alkyl silyl with 1-20 carbon atoms, substituted or unsubstituted cycloalkyl with 3-40 (e.g., 3-20) carbon atoms, substituted or unsubstituted heteroalkyl with 1-20 carbon atoms, substituted or unsubstituted arylalkyl with 7-30 carbon atom numbers, substituted or unsubstituted alkoxy with 1-20 carbon atoms, substituted or unsubstituted aryloxy with 6-30 carbon atoms.

Optionally, R′″, R5, and R6 are independently substituted or unsubstituted cycloalkyl having 3-20 carbon atoms, substituted or unsubstituted heteroalkyl having 1-20 carbon atoms, substituted or unsubstituted aryl alkyl having 7-30 carbon atoms, substituted or unsubstituted alkoxy having 1-20 carbon atoms, or substituted or unsubstituted aryloxy having 6-30 carbon atoms.

In some embodiments, the capping material includes a conjugate diene having a formula of:

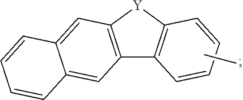

wherein Y is O, S, or

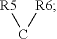

R5 and R6 are independently hydrogen, substituted or unsubstituted alkyl (e.g. substituted or unsubstituted C₁ to C₂₀ alkyl), substituted or unsubstituted heteroalkyl (e.g. substituted or unsubstituted 2 to 20 membered heteroalkyl), substituted or unsubstituted cycloalkyl (e.g. C₃ to C₁₄ cycloalkyl including fused ring structures), substituted or unsubstituted heterocycloalkyl (e.g. 3 to 14 membered heterocycloalkyl including fused ring structures), substituted or unsubstituted aryl (e.g. a C₆ to C₁₄ aryl including fused ring structures), or substituted or unsubstituted heteroaryl (e.g. 5 to 14 membered heteroaryl including fused rings structures).

Optionally, R5 and R6 are independently substituted or unsubstituted cycloalkyl having 3-20 carbon atoms, substituted or unsubstituted heteroalkyl having 1-20 carbon atoms, substituted or unsubstituted aryl alkyl having 7-30 carbon atoms, substituted or unsubstituted alkoxy having 1-20 carbon atoms, or substituted or unsubstituted aryloxy having 6-30 carbon atoms.

In some embodiments, the host material of the hole injection layer or the hole transport material of the hole transport layer has a reorganization energy in a range of 0.1 eV to 0.25 eV. The smaller the reorganization energy, the faster the hole carrier transport rate.

In some embodiments, the guest material of the hole injection layer has a lowest unoccupied molecular orbital energy level greater than 0.5 eV. The inventors of the present disclosure discover that by having this energy level, an excellent doping effect can be achieved to increase hole carrier density.

In some embodiments, a difference between a lowest unoccupied molecular orbital energy level of the guest material of the hole injection layer and a highest occupied molecular orbital energy level of the host material of the hole injection layer is less than 0.3 eV. The inventors of the present disclosure discover that by having this energy level difference, an excellent doping effect can be achieved to increase hole carrier density.

In some embodiments, a difference between a highest occupied molecular orbital energy level of the hole transport layer and a highest occupied molecular orbital energy level of the electron barrier layer is less than 0.2 eV. The inventors of the present disclosure discover that by having this energy level difference, hole carrier accumulation can be reduced to increase effective transport of the hole carriers.

In some embodiments, a difference between a lowest unoccupied molecular orbital energy level of the guest material of the hole injection layer and a work function of the anode is less than 0.4 eV. The inventors of the present disclosure discover that by having this energy level difference, an excellent hole carrier injection from the anode to the hole injection layer can be achieved.

In some embodiments, when the hole injection layer has a thickness of 10 nm and a doping concentration of the guest material in the hole injection layer is 3%, a sheet resistance of the host material of the hole injection layer is equal to or greater than 1*10⁹ 2/sq. Optionally, when the hole injection layer has a thickness of 10 nm and a doping concentration of the guest material in the hole injection layer is 2%, a sheet resistance of the host material of the hole injection layer is equal to or greater than 1*10¹⁰ 2/sq. The inventors of the present disclosure discover that by having the host material and the guest material according to the present disclosure, the horizontal current leakage in the hole injection layer can be significantly reduced.

In some embodiments, the hole injection layer (when the host material is doped with the guest material) has a conductivity in a range of 1*10⁴ S/m to 70*10⁴ S/m.

In some embodiments, a mobility rate of the electron barrier layer is in a range of 1*10⁻⁵ cm²/Vs to 1*10⁻⁴ cm²/Vs. Optionally, hole carrier transmits through the electron barrier layer in a duration less than 3 μs. The inventors of the present disclosure discover that by having this mobility rate, the hole carrier accumulation can be reduced, transport rate of the hole carriers can be increase, and the reduced carrier density due to the one or more large steric hindrance groups introduced into the hole transport material in the hole transport layer can be compensated for.

In some embodiments, the capping layer has an absorption rate greater than 20% with respect to ultraviolet light having a wavelength of 400 nm, and an absorption rate greater than 15% with respect to ultraviolet light having a wavelength of 420 nm. The inventors of the present disclosure discover that by having this absorption rate, the light emitting diode can be protected from the irradiation of external ultraviolet light.

In some embodiments, the capping layer has an absorption rate less than 3% with respect to light having a wavelength in a range of 460 nm to 530 nm, and an absorption rate less than 2% with respect to light having a wavelength in a range of 530 nm to 620 nm. The capping layer has a similar absorption rate for different wavelength ranges in the visible light spectrum, ensuring a balanced color spectrum in the emitted light.

Specific examples of the host materials for the hole injection layer or the host transport material for the hole transport layer include:

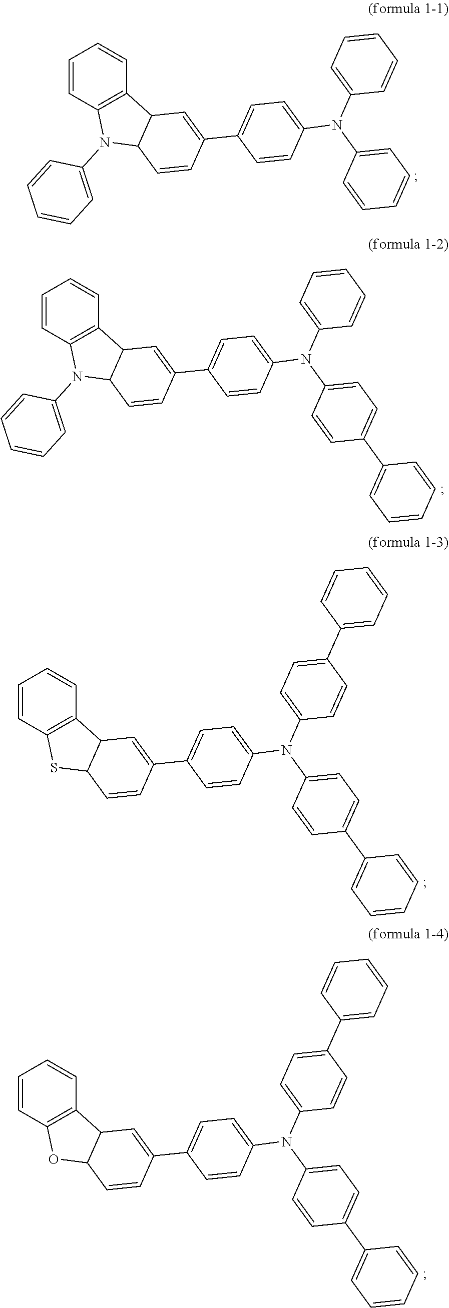

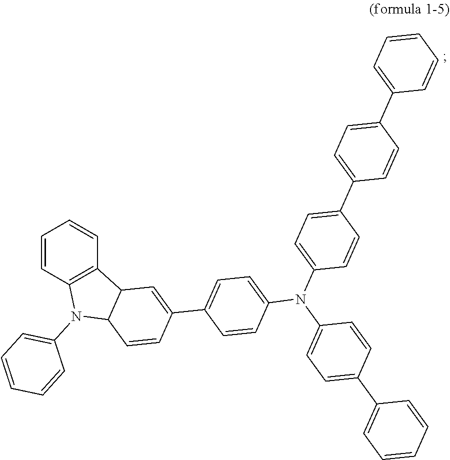 [SMILES: C1=CC2C(C=C1c1ccc(N(c3ccc(-c4ccccc4)cc3)c3ccc(-c4ccc(-c5ccccc5)cc4)cc3)cc1)c1ccccc1N2c1ccccc1]

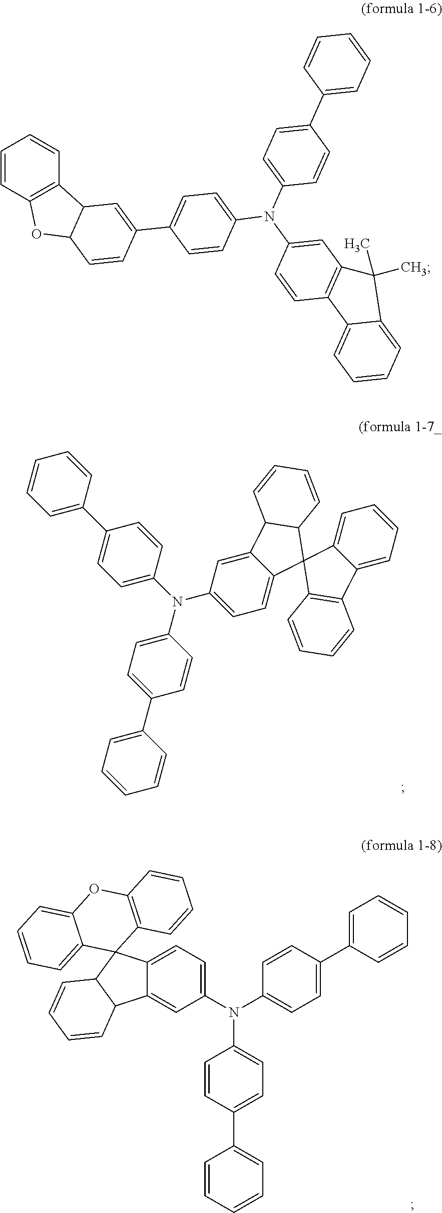 [SMILES: CC1(C)c2ccccc2-c2ccc(N(c3ccc(C4=CC5c6ccccc6OC5C=C4)cc3)c3ccc(-c4ccccc4)cc3)cc21 ; C1=CC2c3cc(N(c4ccc(-c5ccccc5)cc4)c4ccc(-c5ccccc5)cc4)ccc3C3(c4ccccc4-c4ccccc43)C2C=C1 ; C1=CC2c3cc(N(c4ccc(-c5ccccc5)cc4)c4ccc(-c5ccccc5)cc4)ccc3C3(c4ccccc4Oc4ccccc43)C2C=C1]

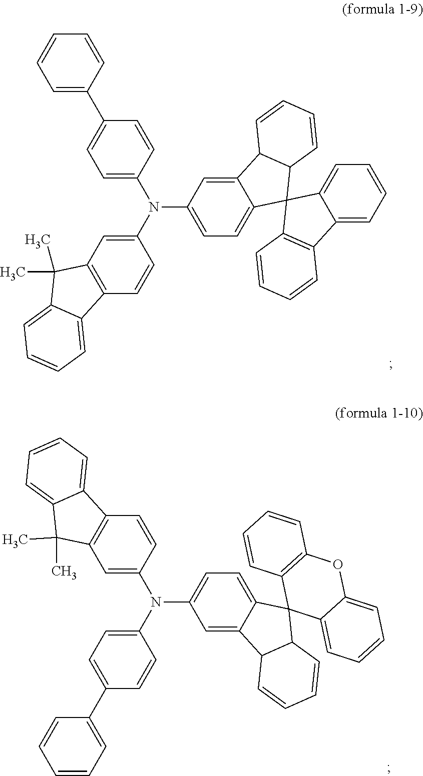 [SMILES: CC1(C)c2ccccc2-c2ccc(N(c3ccc(-c4ccccc4)cc3)c3ccc4c(c3)C3C=CC=CC3C43c4ccccc4-c4ccccc43)cc21 ; CC1(C)c2ccccc2-c2ccc(N(c3ccc(-c4ccccc4)cc3)c3ccc4c(c3)C3C=CC=CC3C43c4ccccc4Oc4ccccc43)cc21]

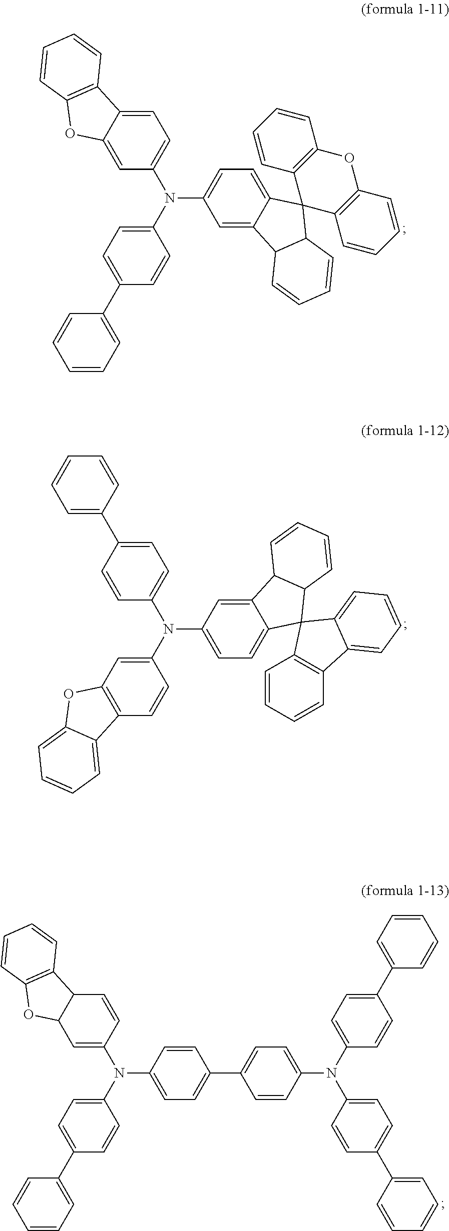 [SMILES: C1=CC2c3cc(N(c4ccc(-c5ccccc5)cc4)c4ccc5c(c4)oc4ccccc45)ccc3C3(c4ccccc4Oc4ccccc43)C2C=C1 ; C1=CC2c3cc(N(c4ccc(-c5ccccc5)cc4)c4ccc5c(c4)oc4ccccc45)ccc3C3(c4ccccc4-c4ccccc43)C2C=C1 ; C1=CC2c3ccccc3OC2C=C1N(c1ccc(-c2ccccc2)cc1)c1ccc(-c2ccc(N(c3ccc(-c4ccccc4)cc3)c3ccc(-c4ccccc4)cc3)cc2)cc1]

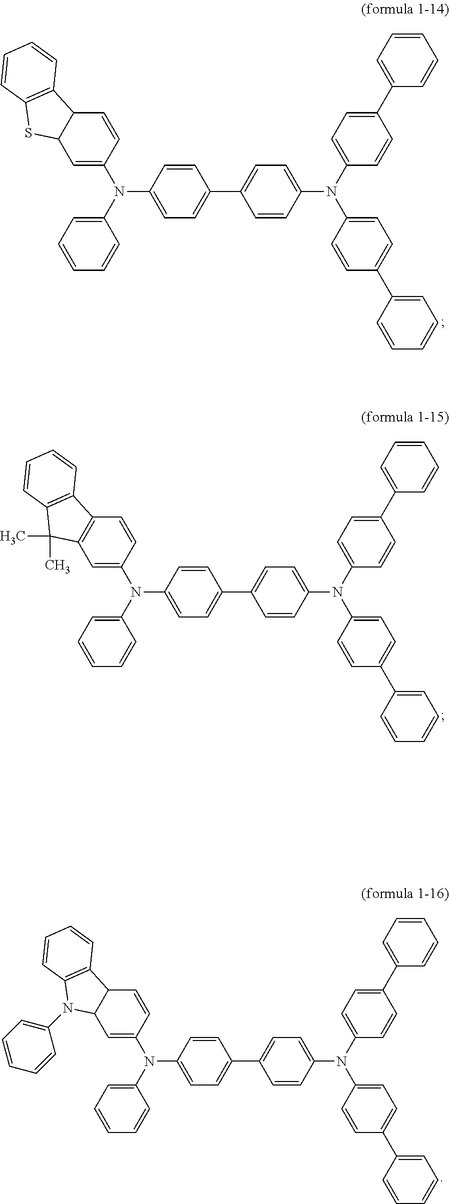 [SMILES: C1=CC2c3ccccc3SC2C=C1N(c1ccccc1)c1ccc(-c2ccc(N(c3ccc(-c4ccccc4)cc3)c3ccc(-c4ccccc4)cc3)cc2)cc1 ; CC1(C)c2ccccc2-c2ccc(N(c3ccccc3)c3ccc(-c4ccc(N(c5ccc(-c6ccccc6)cc5)c5ccc(-c6ccccc6)cc5)cc4)cc3)cc21 ; C1=CC2c3ccccc3N(c3ccccc3)C2C=C1N(c1ccccc1)c1ccc(-c2ccc(N(c3ccc(-c4ccccc4)cc3)c3ccc(-c4ccccc4)cc3)cc2)cc1]

Specific examples of the guest materials for the hole injection layer include.

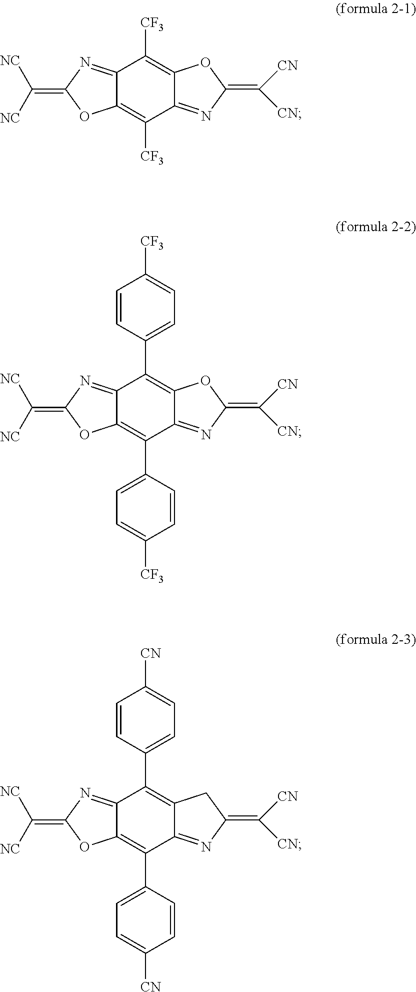 [SMILES: N#CC(C#N)=c1nc2c(C(F)(F)F)c3oc(=C(C#N)C#N)nc3c(C(F)(F)F)c2o1 ; N#CC(C#N)=c1nc2c(-c3ccc(C(F)(F)F)cc3)c3oc(=C(C#N)C#N)nc3c(-c3ccc(C(F)(F)F)cc3)c2o1 ; N#CC(C#N)=C1Cc2c(-c3ccc(C#N)cc3)c3nc(=C(C#N)C#N)oc3c(-c3ccc(C#N)cc3)c2=N1]

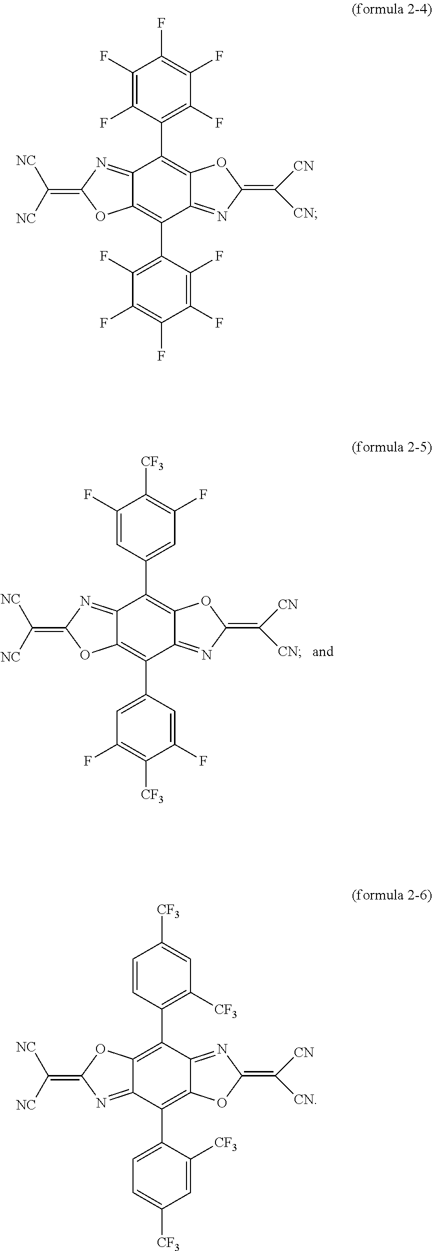 [SMILES: N#CC(C#N)=c1nc2c(-c3c(F)c(F)c(F)c(F)c3F)c3oc(=C(C#N)C#N)nc3c(-c3c(F)c(F)c(F)c(F)c3F)c2o1 ; N#CC(C#N)=c1nc2c(-c3cc(F)c(C(F)(F)F)c(F)c3)c3oc(=C(C#N)C#N)nc3c(-c3cc(F)c(C(F)(F)F)c(F)c3)c2o1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1]

Specific examples of the electron barrier materials for the electron barrier layer include:

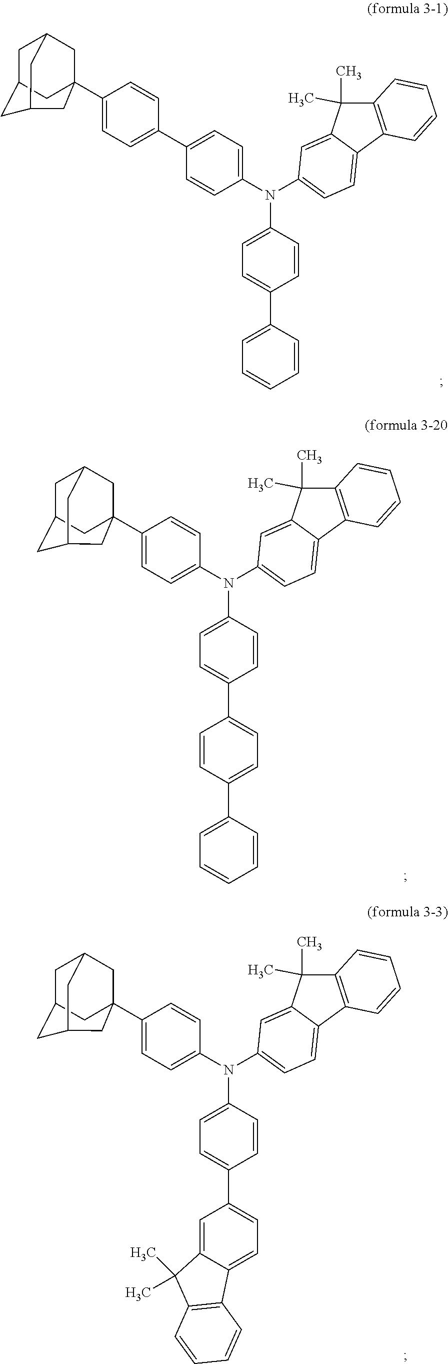 [SMILES: CC1(C)c2ccccc2-c2ccc(N(c3ccc(-c4ccccc4)cc3)c3ccc(-c4ccc(C56CC7CC(CC(C7)C5)C6)cc4)cc3)cc21 ; CC1(C)c2ccccc2-c2ccc(N(c3ccc(-c4ccc(-c5ccccc5)cc4)cc3)c3ccc(C45CC6CC(CC(C6)C4)C5)cc3)cc21 ; CC1(C)c2ccccc2-c2ccc(-c3ccc(N(c4ccc(C56CC7CC(CC(C7)C5)C6)cc4)c4ccc5c(c4)C(C)(C)c4ccccc4-5)cc3)cc21]

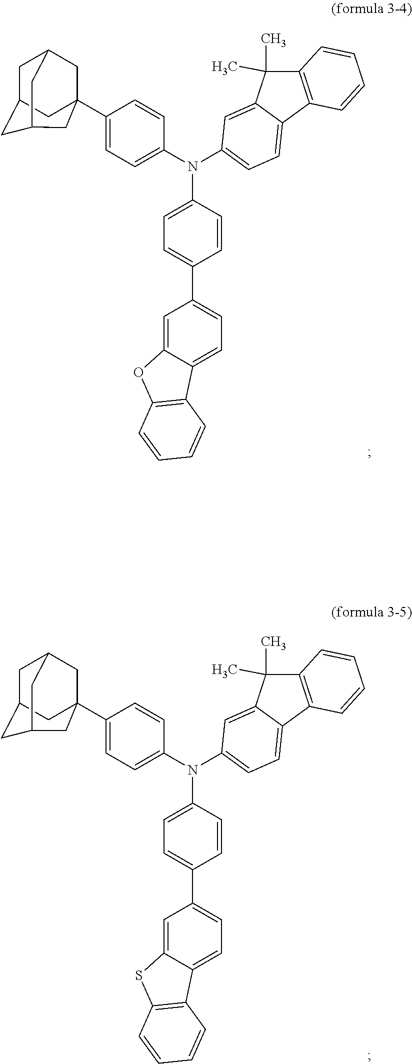 [SMILES: CC1(C)c2ccccc2-c2ccc(N(c3ccc(-c4ccc5c(c4)oc4ccccc45)cc3)c3ccc(C45CC6CC(CC(C6)C4)C5)cc3)cc21 ; CC1(C)c2ccccc2-c2ccc(N(c3ccc(-c4ccc5c(c4)sc4ccccc45)cc3)c3ccc(C45CC6CC(CC(C6)C4)C5)cc3)cc21]

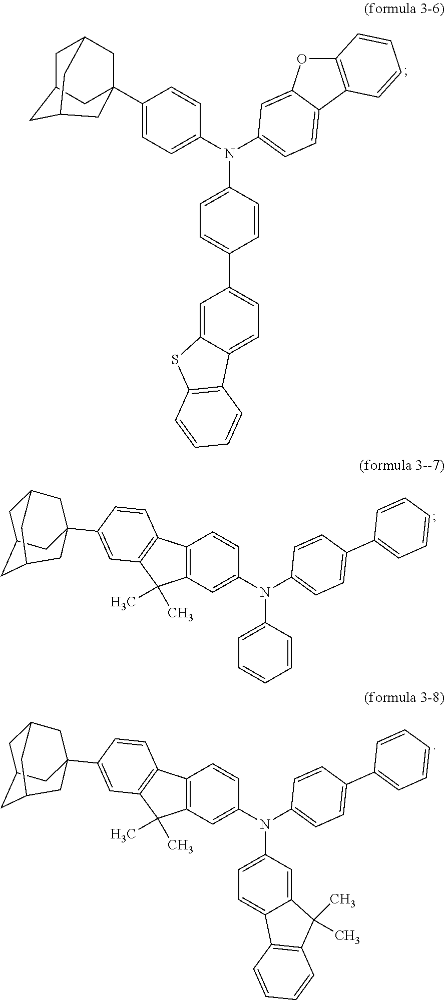 [SMILES: c1ccc2c(c1)oc1cc(N(c3ccc(-c4ccc5c(c4)sc4ccccc45)cc3)c3ccc(C45CC6CC(CC(C6)C4)C5)cc3)ccc12 ; CC1(C)c2cc(N(c3ccccc3)c3ccc(-c4ccccc4)cc3)ccc2-c2ccc(C34CC5CC(CC(C5)C3)C4)cc21 ; CC1(C)c2ccccc2-c2ccc(N(c3ccc(-c4ccccc4)cc3)c3ccc4c(c3)C(C)(C)c3cc(C56CC7CC(CC(C7)C5)C6)ccc3-4)cc21]

Specific examples of the capping materials for the capping layer include:

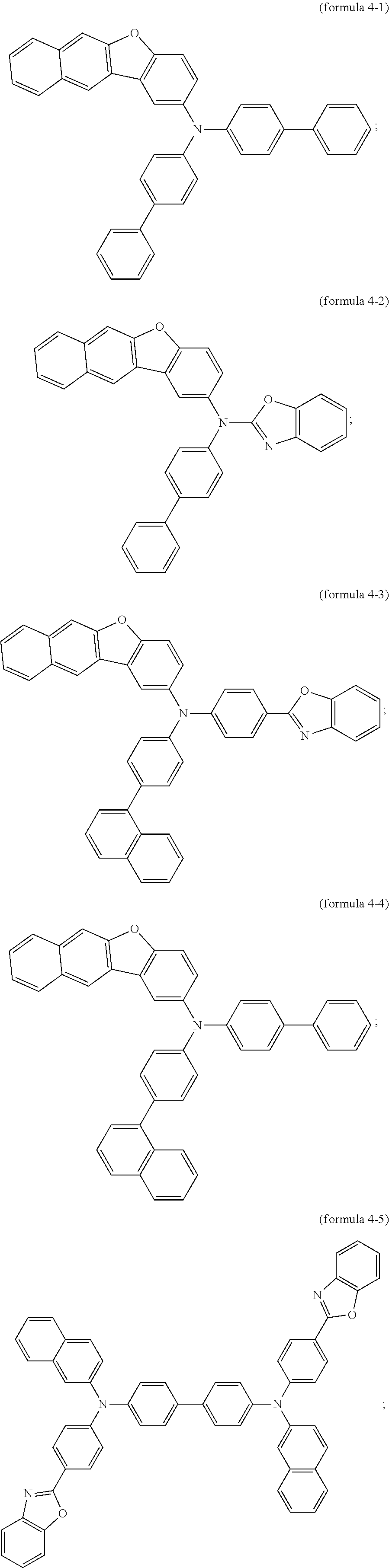 [SMILES: c1ccc(-c2ccc(N(c3ccc(-c4ccccc4)cc3)c3ccc4oc5cc6ccccc6cc5c4c3)cc2)cc1 ; c1ccc(-c2ccc(N(c3ccc4oc5cc6ccccc6cc5c4c3)c3nc4ccccc4o3)cc2)cc1 ; c1ccc2cc3c(cc2c1)oc1ccc(N(c2ccc(-c4nc5ccccc5o4)cc2)c2ccc(-c4cccc5ccccc45)cc2)cc13 ; c1ccc(-c2ccc(N(c3ccc(-c4cccc5ccccc45)cc3)c3ccc4oc5cc6ccccc6cc5c4c3)cc2)cc1 ; c1ccc2cc(N(c3ccc(-c4ccc(N(c5ccc(-c6nc7ccccc7o6)cc5)c5ccc6ccccc6c5)cc4)cc3)c3ccc(-c4nc5ccccc5o4)cc3)ccc2c1]

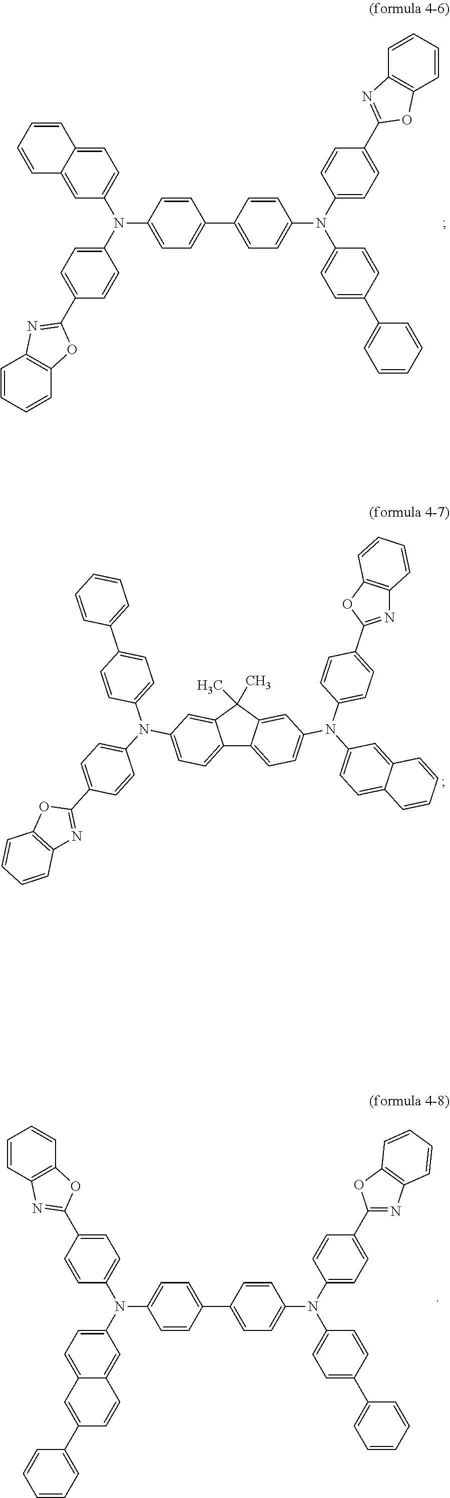 [SMILES: c1ccc(-c2ccc(N(c3ccc(-c4ccc(N(c5ccc(-c6nc7ccccc7o6)cc5)c5ccc6ccccc6c5)cc4)cc3)c3ccc(-c4nc5ccccc5o4)cc3)cc2)cc1 ; CC1(C)c2cc(N(c3ccc(-c4ccccc4)cc3)c3ccc(-c4nc5ccccc5o4)cc3)ccc2-c2ccc(N(c3ccc(-c4nc5ccccc5o4)cc3)c3ccc4ccccc4c3)cc21 ; c1ccc(-c2ccc(N(c3ccc(-c4ccc(N(c5ccc(-c6nc7ccccc7o6)cc5)c5ccc6cc(-c7ccccc7)ccc6c5)cc4)cc3)c3ccc(-c4nc5ccccc5o4)cc3)cc2)cc1]

In another aspect, the present disclosure provides a light emitting diode comprising the organic functional materials according to the present disclosure. In some embodiments, the light emitting diode includes an anode, a light emitting layer, and a cathode on a side of the light emitting layer away from the anode. Optionally, the light emitting diode includes an anode, a hole transport layer according to the present disclosure on the anode, a light emitting layer on a side of the hole transport layer away from the anode, and a cathode on a side of the light emitting layer away from the anode. Optionally, the light emitting diode includes an anode, an electron barrier layer according to the present disclosure on the anode, a light emitting layer on a side of the electron barrier layer away from the anode, and a cathode on a side of the light emitting layer away from the anode. Optionally, the light emitting diode includes an anode, a hole transport layer according to the present disclosure on the anode, an electron barrier layer according to the present disclosure on a side of the hole transport layer away from the anode, a light emitting layer on a side of the electron barrier layer away from the anode, and a cathode on a side of the light emitting layer away from the anode.

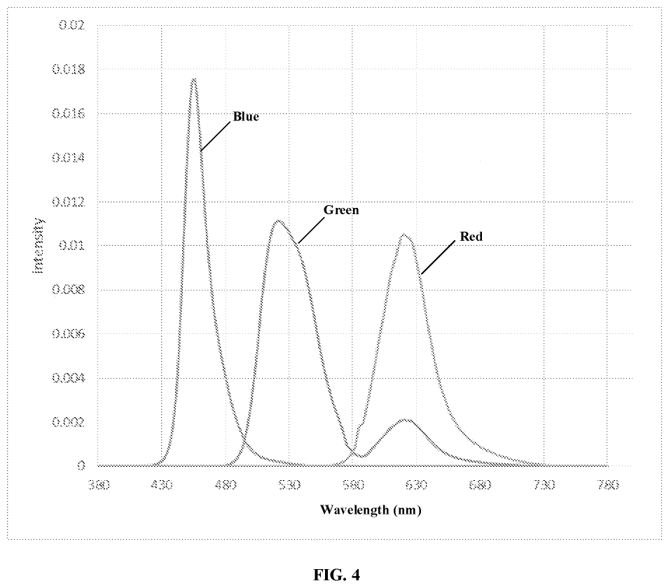

FIG. 3 illustrates the structure of a light emitting diode in some embodiments according to the present disclosure. Referring to FIG. 3, the light emitting diode in some embodiments includes an anode AD, a hole injection layer HIL, on the anode AD, a hole transport layer HTL on a side of the hole injection layer HIL, away from the anode AD, an electron barrier layer EBL on a side of the hole transport layer HTL away from the anode AD, a light emitting layer EL on a side of the electron barrier layer EBL away from the anode AD, a hole barrier layer HBL on a side of the light emitting layer EL away from the anode AD, an electron transport layer ETL on a side of the hole barrier layer HBL away from the anode AD, an electron injection layer EIL on a side of the electron transport layer ETL away from the anode AD, a cathode CD on a side of the electron injection layer EIL away from the anode AD, and a capping layer CAP on a side of the cathode CD away from the anode.

Various appropriate hole injection materials may be used for making the hole injection layer. The hole injection layer in some embodiments includes a host material and a guest material. Examples of the host materials include those described in the present disclosure. Additional examples of the host materials include polythiophene, polyaniline, polypyrrole, copper phthalocyanine and 4,4′,4″-tris(N,N-phenyl-3-methylphenylamino)triphenylamine (m-MTDATA), MoO3, CuPc, poly(3,4-ethylenedioxythiophene)polystyrene sulfonate (PEDOT:PSS), or any combination thereof. Examples of the guest materials include those described in the present disclosure. Additional examples of the guest materials include hexacyanohexaazatritylenes, 2,3,5,6-tetrafluoro-7,7,8,8-tetracyano-p-quinodimethane (F4TCNQ), 1, 2, 3-tris[(cyano) (4-cyano-2,3,5,6-tetrafluorophenyl) methylene]cyclopropane, or any combination thereof.

Various appropriate hole transport materials may be used for making the hole transport layer. Examples of appropriate hole transport materials include those described in the present disclosure. Additional examples of the hole transport materials include various p-type polymer materials and various p-type low-molecular-weight materials, e.g., polythiophene, polyaniline, polypyrrole, and a mixture having poly-3,4-ethylenedioxythiophene and poly(sodium-p-styrenesulfonate), 4,4′-cyclohexylidene bis[N,N-bis(4-methylphenyl)benzenamine (TAPC), 4,4′,4″-tris(N-carbazolyl)triphenylamine (TCTA), N,N′-di(1-naphthyl)-N,N′-diphenylbenzidine (NPB), or any combination thereof.

Various appropriate electron barrier materials may be used for making the electron barrier layer. Examples of appropriate electron barrier materials include those described in the present disclosure. Additional examples of the electron barrier materials include aromatic amines and dimethylfluorene or carbazole materials such as 4,4′-Bis[N-(1-naphthyl)-N-phenylamino]biphenyl (NPB), N,N′-bis(3-methylphenyl)-N,N′-diphenyl-[1,1′-biphenyl]-4,4′-diamine (TPD), 4-phenyl-4′-(9-phenylfluoren-9-yl)triphenylamine (BAFLP), 4,4′-bis[N-(9,9-dimethylfluoren-2-yl)-N-phenylamino]biphenyl (DFLDPBi), 4,4′-bis[N-(9,9-dimethylfluoren-2-yl)-N-phenylamino]biphenyl 4,4′-bis(9-carbazolyl)biphenyl (CBP), 9-phenyl-3-[4-(10-phenyl-9-anthracenyl)phenyl]-9H-carbazole (PCzPA), or any combination thereof.

Various appropriate light emitting materials may be used for making the light emitting layer. Examples of appropriate blue light emitting materials include pyrene derivatives, anthracene derivatives, fluorene derivatives, perylene derivatives, styrylamine derivatives, metal complexes, etc. N1,N6-bis([1,1′-biphenyl]-2-yl)-N1,N6-bis([1,1′-biphenyl]-4-yl)pyrene-1,6-diamine, 9,10-di-(2-naphthyl)anthracene (ADN), 2-methyl 9,10-di-2-naphthylanthracene (MADN), 2,5,8,11-tetra-tert-butyl perylene (TBPe), 4,4′-bis[4-(diphenylamino)styryl]biphenyl (BDAV Bi), 4,4′-bis[4-(di-p-tolylamino)styryl]biphenyl (DPAVBi), bis(4,6-difluorophenyl pyridine-C2,N)pyridinecarbonitrile iridium (FIrpic), or any combination thereof.

Examples of appropriate green light emitting materials include coumarin dyes, quinacridine copper derivatives, polycyclic aromatic hydrocarbons, diaminoanthracene derivatives, carbazole derivatives, metal complexes, etc. Coumarin 6 (C-6), coumarin 545T (C-525T), quinacridine copper (QA), N,N′-dimethylquinacridone (DMQA), 5,12-diphenylnaphthalene (DPT), N10,N10′-diphenyl-N10,N10′-dinaphthalenyl-9,9′-bianthracene-10, 10′-diamine (BA-NPB), tris(8-hydroxyquinoline) Al(III) (Alq3), tris(2-phenylpyridine)iridium (Ir(ppy)₃), di(2-phenylpyridine)iridium acetyl pyruvate (Ir(ppy)₂(acac)), or any combination thereof.

Examples of appropriate red light emitting materials include DCM series materials, metal complexes, 4-(dicyanomethylene)-2-methyl-6-(4-dimethylaminostyryl)-4H-pyran (DCM), 4-(dicyanomethylene)-2-tert-butyl-6-(1,1,7,7-tetramethyljulolidin-9-enyl)-4H-pyran (DCJTB), bis(1-phenylisoquinoline) (acetylacetonato)iridium(III) (Ir(piq)2(acac)), platinum octaethylporphyrin (PtOEP), bis(2-(2′-benzothienyl)pyridine-N,C3′) (acetylacetonate)iridium (Ir(btp)2 (acac)), or any combination thereof.

Various appropriate hole barrier materials or electron transport materials may be used for making the hole barrier layer or the electron transport layer. Examples of appropriate hole barrier materials or electron transport materials include aromatic heterocyclic compounds such as imidazole derivatives such as benzimidazole derivatives, imidazolopyridine derivatives, benzimidazolopyridine derivatives, etc.; zine derivatives such as pyrimidine derivatives, triazine derivatives, etc.; quinoline derivatives, isoquinoline derivatives, phenanthroline derivatives, etc. containing a nitrogen-containing six-membered ring structure (also including those having a substituent of the phosphine oxide system on the heterocyclic compounds), etc. 2-(4-biphenyl)-5-(4-tert-butylphenyl)-1,3,4-oxadiazole (PBD), 1,3-bis[5-(p-tert-butylphenyl)-1,3,4-oxadiazol-2-yl]benzene (OXD-7), 3-(4-tert-butylphenyl)-4-phenyl-5-(4-biphenyl)-1,2,4-triazole (TAZ), 3-(4-tert-Butylphenyl)-4-(4-Ethyl phenyl)-5-(4-biphenyl)-1,2,4-triazole (p-EtTAZ), red phenanthroline (BPhen), 2,9-dimethyl-4,7-diphenyl-1,10-phenanthroline (BCP), 4,4′-bis(5-methylbenzoxazol-2-yl)astragalus (BzOs), or any combination thereof. Additional examples of the electron transport materials include 4,7,-diphenyl-1,10-phenanthroline, 2,9-Bis(naphthalen-2-yl)-4,7-diphenyl-1,10-phenanthroline, 2,9-dimethyl-4,7-diphenyl-1,10-phenanthroline, 8-hydroxyquinoline aluminum, 8-hydroxyquinoline lithium, Bis(8-hydroxy-2-methylquinoline)-(4-phenylphenoxy)aluminum, tris(8-quinolinolate)aluminum, 3-(biphenyl-4-yl)-5-(4-tertbutylphenyl)-4-phenyl-4H-1,2,4-triazole, bis(10-hydroxybenzo[h]quinolinato beryllium), 1,3,5-tris(N-phenylbenzimiazole-2-yl)benzene, or any combination thereof.

Various appropriate electron injection materials may be used for making the electron injection layer. Examples of appropriate electron injection materials include alkali metals or metals, such as LiF, Yb, Mg, Ca or their compounds.

Table 1 shows a comparison on performance and properties between a related light emitting diode and several light emitting diodes according to the present disclosure.

| | | External | |
|---|---|---|---|
| | | quantum | Life time |
| | Voltage | efficiency | (LT95@1000 nit) |
| A related light emitting diode | 100% | 100% | 100% |
| Light emitting diode 1 according | 98% | 105% | 108% |
| to the present disclosure | | | |
| Light emitting diode 2 according | 99% | 104% | 104% |
| to the present disclosure | | | |
| Light emitting diode 3 according | 97% | 109% | 106% |
| to the present disclosure | | | |
| Light emitting diode 4 according | 97% | 107% | 106% |
| to the present disclosure | | | |
| Light emitting diode 5 according | 98% | 105% | 103% |
| to the present disclosure | | | |
| Light emitting diode 6 according | 97% | 111% | 105% |
| to the present disclosure | | | |

In Table 1, the related light emitting diode includes an anode comprising indium tin oxide;
a hole injection layer having a guest material of:

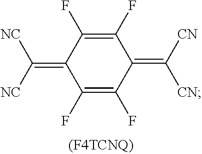 [SMILES: N#CC(C#N)=c1c(F)c(F)c(=C(C#N)C#N)c(F)c1F]

a hole injection layer having a host material of

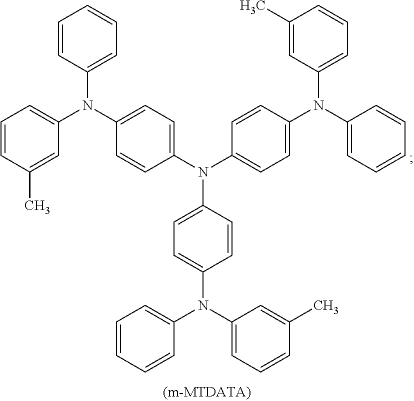 [SMILES: Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1]

a hole transport layer having a hole transport material of:

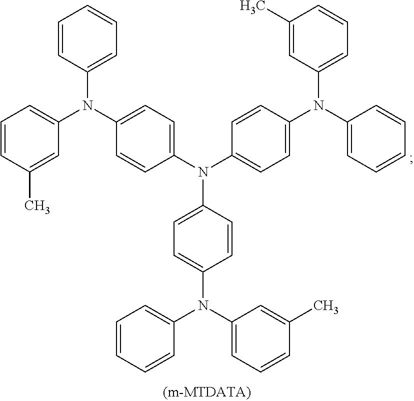 [SMILES: Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1]

an electron barrier layer having an electron barrier material of:

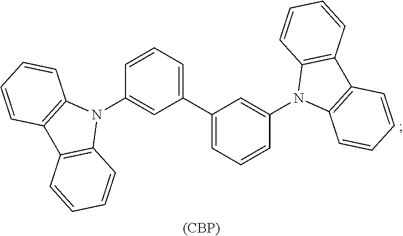 [SMILES: c1cc(-c2cccc(-n3c4ccccc4c4ccccc43)c2)cc(-n2c3ccccc3c3ccccc32)c1 ; "(CBP)"]

a hole barrier layer having a hole barrier material of:

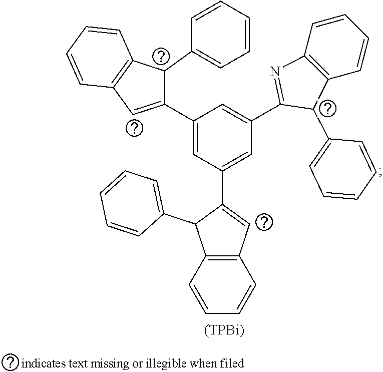

an electron transport layer having an electron transport material of:

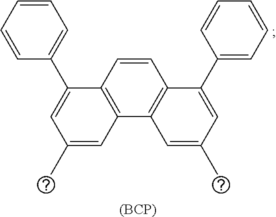 [SMILES: Cc1cc(-c2ccccc2)c2ccc3c(-c4ccccc4)cc(C)cc3c2c1 ; "(BCP)"]

a blue light emitting layer having a host material of:

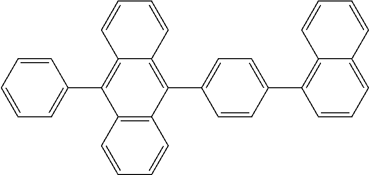 [SMILES: c1ccc(-c2c3ccccc3c(-c3ccc(-c4cccc5ccccc45)cc3)c3ccccc23)cc1]

(9-[4-(naphthalen-1-yl)phenyl]-10-phenylanthracene);
a blue light emitting layer having a guest material of:

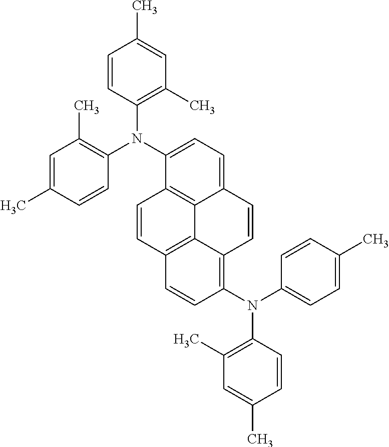

(N1,N1,N6-tris(2,4-dimethylphenyl)-N6-(4-methylphenyl)pyrene-1,6-diamine);
a green light emitting layer having a host material of:

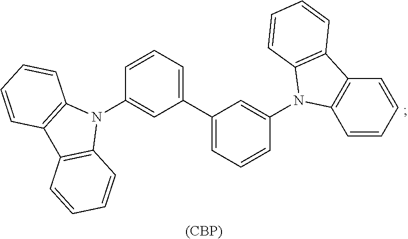 [SMILES: c1cc(-c2cccc(-n3c4ccccc4c4ccccc43)c2)cc(-n2c3ccccc3c3ccccc32)c1 ; "(CBP)"]

a green light emitting layer having a guest material of:

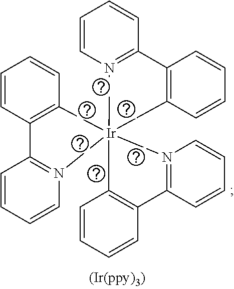

a red light emitting layer having a host material of:

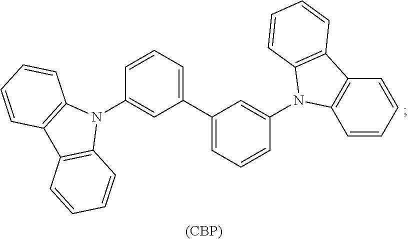 [SMILES: c1cc(-c2cccc(-n3c4ccccc4c4ccccc43)c2)cc(-n2c3ccccc3c3ccccc32)c1 ; "(CBP)"]

a red light emitting layer having a guest material of:

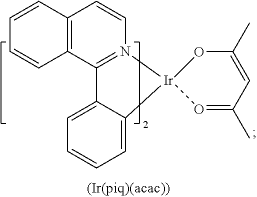

and
a capping layer having a capping material of:

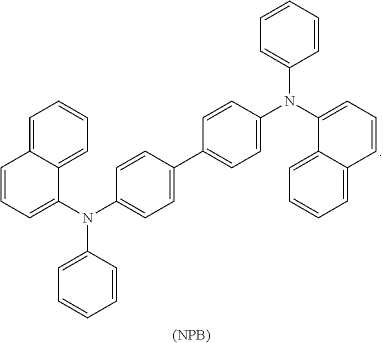

In Table 1, the hole injection layer has a thickness of 10 nm and a 3% F4TCNQ doping concentration, the hole transport layer has a thickness of 100 nm, the electron barrier layer has a thickness of 40 nm, the light emitting layer has a thickness of 45 nm and a 3% doping concentration, the hole barrier layer has a thickness of 5 nm, the electron transport layer has a thickness of 30 nm, the electron injection layer having a thickness of 1 nm and comprising Yb, the cathode layer has a thickness of 13 nm and comprising magnesium and silver laminate, and the capping layer has thickness of 60 nm.

In Table 1, the thicknesses and compositions of the anode, the light emitting layer, the electrode transport layer, the electron injection layer, the cathode, and the capping layer in the light emitting diodes 1-6 according to the present disclosure are the same as the related light emitting diode discussed above.

The thicknesses of the hole injection layer and the hole transport layer in the light emitting diodes 1-6 according to the present disclosure are different from those in the related light emitting diode discussed above.

The doping concentration (3%) of the hole injection layer in the light emitting diodes 1-6 according to the present disclosure is the same as that in the related light emitting diode discussed above.

The thickness of the electron barrier layer in the light emitting diodes 1-6 according to the present disclosure is different from that in the related light emitting diode discussed above. Specifically, the thickness of the electron barrier layer in the light emitting diodes 1-6 according to the present disclosure is 80 nm.

The compositions of the hole injection layer, the hole transport layer, and the electron barrier layer in the light emitting diodes 1-6 according to the present disclosure are different from those in the related light emitting diode discussed above.

In the light emitting diodes 1 to 3 according to the present disclosure, the electron barrier layer includes an electron barrier material having the formula 3-1 as discussed above.

In the light emitting diodes 4 to 6 according to the present disclosure, the electron barrier layer includes an electron barrier material having the formula 3-3 as discussed above.

In the light emitting diodes 1 to 6 according to the present disclosure, the guest material of the hole injection layer includes a material having the formula 2-6 as discussed above.

In the light emitting diodes 1 and 4 according to the present disclosure, the hole material of the hole injection layer and the hole transport material of the hole transport layer include a material having the formula 1-2 as discussed above.

In the light emitting diodes 2 and 5 according to the present disclosure, the hole material of the hole injection layer and the hole transport material of the hole transport layer include a material having the formula 1-7 as discussed above.

In the light emitting diodes 3 and 6 according to the present disclosure, the hole material of the hole injection layer and the hole transport material of the hole transport layer include a material having the formula 1-12 as discussed above.

As shown in Table 1, as compared to the related light emitting diode, the light emitting diodes according to the present disclosure have significantly improved properties and performance. For example, the external quantum efficiency of the light emitting diodes according to the present disclosure increases by at least 4% to 11%. Life time of the light emitting diodes according to the present disclosure increases by at least 4% to 8%.

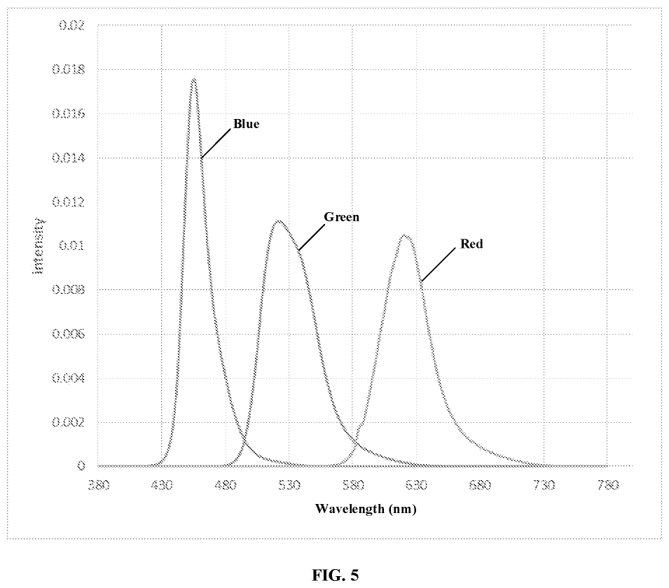

FIG. 4 shows a light emission spectrum in a related light emitting diode. As shown in FIG. 4, when a green subpixel is configured to emit light while the red subpixel is turned off, residual light emission is nonetheless observed in the red subpixel due to the horizontal current leakage in the common layers such as the hole injection layer HIL, resulting in color cross-talk. FIG. 5 shows a light emission spectrum in a light emitting diode in some embodiments according to the present disclosure. As shown in FIG. 5, the issue of color cross-talk is substantially obviated in the light emitting diode according to the present disclosure.

In another aspect, the present disclosure provides a display substrate including the light emitting diode described herein or fabricated by a method described herein, and a pixel driving circuit configured to drive light emission of the light emitting diode.

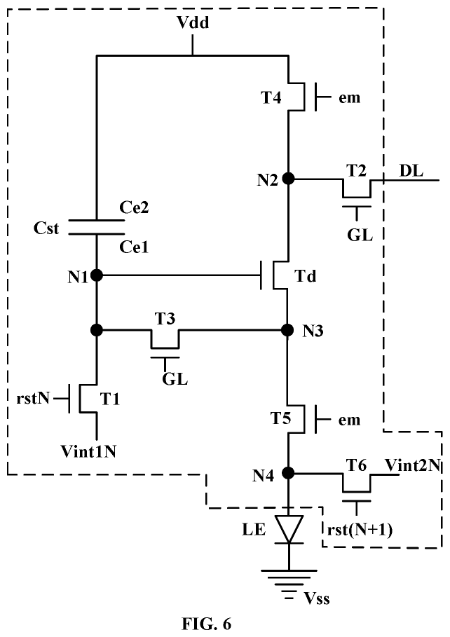

FIG. 6 is a circuit diagram illustrating the structure of a pixel driving circuit in some embodiments according to the present disclosure. Referring to FIG. 6, in some embodiments, the respective pixel driving circuit includes a driving transistor Td; a storage capacitor Cst having a first capacitor electrode Ce1 and a second capacitor electrode Ce2; a first transistor T1 having a gate electrode connected to a respective reset control signal line rstN in a present stage (or a present row) of a plurality of reset control signal lines, a first electrode connected to a respective first reset signal line Vint1N in a present stage (or a present row) of a plurality of first reset signal lines, and a second electrode connected to a first capacitor electrode Ce1 of the storage capacitor Cst and a gate electrode of the driving transistor Td; a second transistor T2 having a gate electrode connected to a respective gate line of a plurality of gate lines GL, a first electrode connected to a respective data line of a plurality of data lines DL, and a second electrode connected to a first electrode of the driving transistor Td; a third transistor T3 having a gate electrode connected to the respective gate line, a first electrode connected to the first capacitor electrode Ce1 of the storage capacitor Cst and the gate electrode of the driving transistor Td, and a second electrode connected to a second electrode of the driving transistor Td; a fourth transistor T4 having a gate electrode connected to a respective light emitting control signal line of a plurality of light emitting control signal lines em, a first electrode connected to a respective voltage supply line of a plurality of voltage supply lines Vdd, and a second electrode connected to the first electrode of the driving transistor Td and the second electrode of the second transistor T2; a fifth transistor T5 having a gate electrode connected to the respective light emitting control signal line, a first electrode connected to second electrodes of the driving transistor Td and the third transistor T3, and a second electrode connected to an anode of a light emitting element LE; and a sixth transistor T6 having a gate electrode connected to a respective reset control signal line rst(N+1) in a next adjacent stage (or a next adjacent row) of a plurality of reset control signal lines, a first electrode connected to a respective second reset signal line Vint2N in the present stage (or the present row) of the plurality of second reset signal lines, and a second electrode connected to the second electrode of the fifth transistor and the anode of the light emitting element LE. The second capacitor electrode Ce2 is connected to the respective voltage supply line and the first electrode of the fourth transistor T4.

In another aspect, the present disclosure provides a display apparatus including the display substrate described herein or fabricated by a method described herein, and one or more integrated circuits connected to the display substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a mini light emitting diode display apparatus. Optionally, the display apparatus is a quantum dots light emitting diode display apparatus.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A light emitting diode, comprising:
a hole injection layer; and
at least one of a hole transport layer or an electron barrier layer;
wherein the hole injection layer comprises a host material doped with a guest material;
wherein the host material comprises an aromatic material having one or more large steric hindrance groups.

2. The light emitting diode of claim 1, wherein the aromatic material having one or more large steric hindrance groups has a formula of: 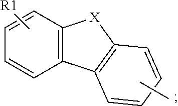
wherein X is —O—, —S—, 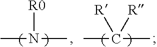
and
R0, R′, R″, and R1 are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted aryl alkyl, substituted or unsubstituted alkyl silyl, or substituted or unsubstituted aryl silyl.

3. The light emitting diode of claim 1, wherein the aromatic material having one or more large steric hindrance groups has a formula of: 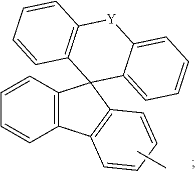
wherein —Y— is a single bond, —O—, —S—, 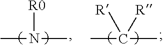
and
R0, R′, and R″ are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted aryl alkyl, substituted or unsubstituted alkyl silyl, or substituted or unsubstituted aryl silyl.

4. The light emitting diode of claim 1, wherein the guest material of the hole injection layer comprises a cyanide group and fluorine element.

5. The light emitting diode of claim 4, wherein the guest material has a formula of: 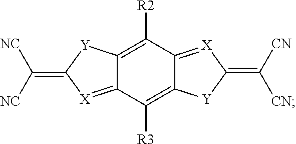
X is N, or C—R4; Y is O, S, or 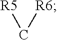
R2 and R3 contain one or more fluorine atoms, and are independently substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted aryl alkyl, substituted or unsubstituted alkoxy, or substituted or unsubstituted aryloxy; and
R4, R5, and R6 are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted aryl alkyl, substituted or unsubstituted alkoxy, or substituted or unsubstituted aryloxy.

6. The light emitting diode of claim 1, wherein a difference between a lowest unoccupied molecular orbital energy level of the guest material of the hole injection layer and a highest occupied molecular orbital energy level of a host material of the hole injection layer is less than 0.3 eV.

7. The light emitting diode of claim 1, wherein, when the hole injection layer has a thickness of 10 nm and a doping concentration of the guest material in the hole injection layer is 3%, a sheet resistance of the host material of the hole injection layer is equal to or greater than 1*10⁹ Ω/sq.

8. The light emitting diode of claim 1, wherein, when the hole injection layer has a thickness of 10 nm and a doping concentration of the guest material in the hole injection layer is 2%, a sheet resistance of the host material of the hole injection layer is equal to or greater than 1*10¹⁰ Ω/sq.

9. The light emitting diode of claim 1, further comprising the hole transport layer including a host transport material;
wherein the host transport material comprises an aromatic material having one or more large steric hindrance groups.

10. The light emitting diode of claim 9, wherein the aromatic material having one or more large steric hindrance groups has a formula of: 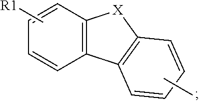
wherein X is —O—, —S—, 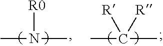
and
R0, R′, R″, and R1 are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted aryl alkyl, substituted or unsubstituted alkyl silyl, or substituted or unsubstituted aryl silyl.

11. The light emitting diode of claim 9, wherein the aromatic material having one or more large steric hindrance groups has a formula of: 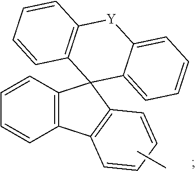
wherein —Y— is a single bond, —O—, —S—, 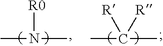
and
R0, R′, and R″ are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted aryl alkyl, substituted or unsubstituted alkyl silyl, or substituted or unsubstituted aryl silyl.

12. The light emitting diode of claim 1, further comprising the electron barrier layer;
wherein the electron barrier layer comprises an electron barrier material including an aromatic material having a dibenzo group and an adamantyl group; and
wherein the adamantyl group has a formula of

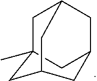

13. The light emitting diode of claim 12, wherein the dibenzo group has a formula of: 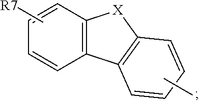
wherein X is —O—, —S—, 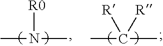
and
R7 is substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted aryl alkyl, substituted or unsubstituted alkyl silyl, or substituted or unsubstituted aryl silyl.

14. The light emitting diode of claim 1, wherein a difference between a highest occupied molecular orbital energy level of the hole transport layer and a highest occupied molecular orbital energy level of the electron barrier layer is less than 0.2 eV.

15. The light emitting diode of claim 1, wherein a mobility rate of the electron barrier layer is in a range of 1*10⁻⁵ cm²/Vs to 1*10⁻⁴ cm²/Vs.

16. The light emitting diode of claim 1, wherein hole carrier transmits through the electron barrier layer in a duration less than 3 μs.

17. The light emitting diode of claim 1, further comprising a cathode layer and a capping layer on a side of the cathode layer away from the hole injection layer;
wherein the capping material comprises a conjugate diene having a formula of: 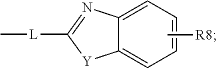
wherein Y is O, S, or 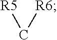
L is bond, substituted or unsubstituted alkylene, substituted or unsubstituted heteroalkylene, substituted or unsubstituted cycloalkylene, substituted or unsubstituted heterocycloalkylene, substituted or unsubstituted arylene, substituted or unsubstituted heteroarylene, —N(R′″)—, —C(O)—, or —O—;
R8 is hydrogen, deuterium, halide, substituted or unsubstituted alkyl, substituted or unsubstituted heteroalkyl, substituted or unsubstituted cycloalkyl, substituted or unsubstituted heterocycloalkyl, substituted or unsubstituted aryl, substituted or unsubstituted heteroaryl, substituted or unsubstituted alkyl silyl, or substituted or unsubstituted aryl silyl; and
R′″, R5, and R6 are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl.

18. The light emitting diode of claim 1, further comprising a cathode layer and a capping layer on a side of the cathode layer away from the hole injection layer;
wherein the capping material comprises a conjugate diene having a formula of: 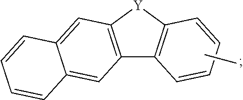
wherein Y is O, S, or 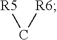
and
R5 and R6 are independently hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl, or substituted or unsubstituted heteroaryl.

19. The light emitting diode of claim 1, further comprising a cathode layer and a capping layer on a side of the cathode layer away from the hole injection layer;
wherein the capping layer has an absorption rate greater than 20% with respect to ultraviolet light having a wavelength of 400 nm, and an absorption rate greater than 15% with respect to ultraviolet light having a wavelength of 420 nm; and
the capping layer has an absorption rate less than 3% with respect to light having a wavelength in a range of 460 nm to 530 nm, and an absorption rate less than 2% with respect to light having a wavelength in a range of 530 nm to 620 nm.

20. A display apparatus, comprising the light emitting diode of claim 1, and a pixel driving circuit configured to drive light emission of the light emitting diode.
